(19) United States
(12) Patent Application Publication
(10) Pub. No.: US 2002/0125044 A1
(43) Pub. Date: Sep. 12, 2002

(54) Layered circuit boards and methods of production thereof

(76) Inventor: Henry Johnson, Elk Mound, WI (US)

Correspondence Address: Honeywell International Inc., Law Dept. AB2, P.O. Box 2245, 101 Colombia Road, Morristown, NJ, 07962, US

(21) Appl. No.: 09/752,658

(22) Filed: Dec. 28, 2000

(51) Int. Cl. H05K 1/03; H05K 1/09; H05K 3/06

(52) U.S. Cl. 174/262; 428/209; 29/846; 29/852; 174/255

(57) ABSTRACT

Compositions and methods are provided whereby sublamination materials and layers may be produced that comprise a) a single layer etched reference plane having a top surface and a bottom surface; b) a first signal layer coupled to the top surface with a core material; c) a second signal layer coupled to the bottom surface with a bond-ply material; and d) at least one of a blind or a micro via. Printed wiring boards may be produced that comprise a) a substrate layer, and b) a sublamination layer laminated onto the substrate layer, and c) at least one additional layer coupled to the sublamination layer or material.

### FIELD OF THE INVENTION

The field of the invention is electronic components.

### BACKGROUND OF THE INVENTION

Electronic components are used in ever increasing numbers of consumer and commercial electronic products. Examples of some of these consumer and commercial products are televisions, personal computers, Internet servers, cell phones, pagers, palm-type organizers, portable radios, car stereos, or remote controls. As the demand for these consumer and commercial electronics increases, there is also a demand for those same products to become smaller, more finctional, and more portable for the consumers and businesses.

As a result of the size decrease in these products, the components that comprise the products must also become smaller. Examples of some of those components that need to be reduced in size or scaled down are printed circuit or wiring boards, resistors, wiring, keyboards, touch pads, and chip packaging.

Components, therefore, are being broken down and investigated to determine if there are better building materials and methods that will allow them to be scaled down to accommodate the demands for smaller electronic components. In layered components, one goal appears to be decreasing the number of the layers at the same time increasing the layers routing density. This task can be difficult, however, given that several of the layers and components of the layers should generally be present in order to operate the device.

Thus, there is a continuing need to a) design and produce layered materials that meet customer specifications while minimizing the size of the device and number of layers, and b) develop reliable methods of producing desired layered materials and components comprising those layered materials.

### SUMMARY OF THE INVENTION

Lamination materials and layers contemplated herein may be produced that comprise a) a single layer etched reference plane having a top surface and a bottom surface; b) a first signal layer coupled to the top surface with a core material; c) a second signal layer coupled to the bottom surface with a bond-ply material; and d) at least one of a blind or a micro via.

It is even further contemplated that printed wiring boards may be produced that comprise a) a substrate layer, and b) a sublamination layer laminated onto the substrate layer, and c) at least one additional layer coupled to the sublamination layer or material.

Various objects, features, aspects and advantages of the present invention will become more apparent from the following detailed description of preferred embodiments of the invention, along with the accompanying drawings in which like numerals represent like components.

### BRIEF DESCRIPTION OF THE DRAWINGS

FIG. 1 is a schematic diagram of a conventional two-layer lamination material.

FIG. 2 is a schematic diagram of a preferred embodiment.

FIG. 3 is a flowchart showing a method of preparing a preferred embodiment.

FIG. 4 is a schematic diagram of a preferred embodiment.

Table 1 is a compilation of some preferred materials and their physical characteristics.

### DETAILED DESCRIPTION

Electronic components, as contemplated herein, are generally thought to comprise any layered component that can be utilized in an electronic-based product. Contemplated electronic components comprise circuit boards, chip packaging, dielectric components of circuit boards, printed-wiring boards, and other components of circuit boards, such as capacitors, inductors, and resistors.

Electronic-based products can be “finished” in the sense that they are ready to be used in industry or by other consumers. Examples of finished consumer products are a television, a computer, a cell phone, a pager, a palm-type organizer, a portable radio, a car stereo, and a remote control. Also contemplated are “intermediate” products such as circuit boards, chip packaging, and keyboards that are potentially utilized in finished products.

Electronic products may also comprise a prototype component, at any stage of development from conceptual model to final scale-up mock-up. A prototype may or may not contain all of the actual components intended in a finished product, and a prototype may have some components that are constructed out of composite material in order to negate their initial effects on other components while being initially tested.

Electronic products and components may comprise layered materials, layered components, and components that are laminated in preparation for use in the component or product. Sublamination layers, lamination layers or “sublam” layers, along with other layers, generally make up the finished layered component or product.

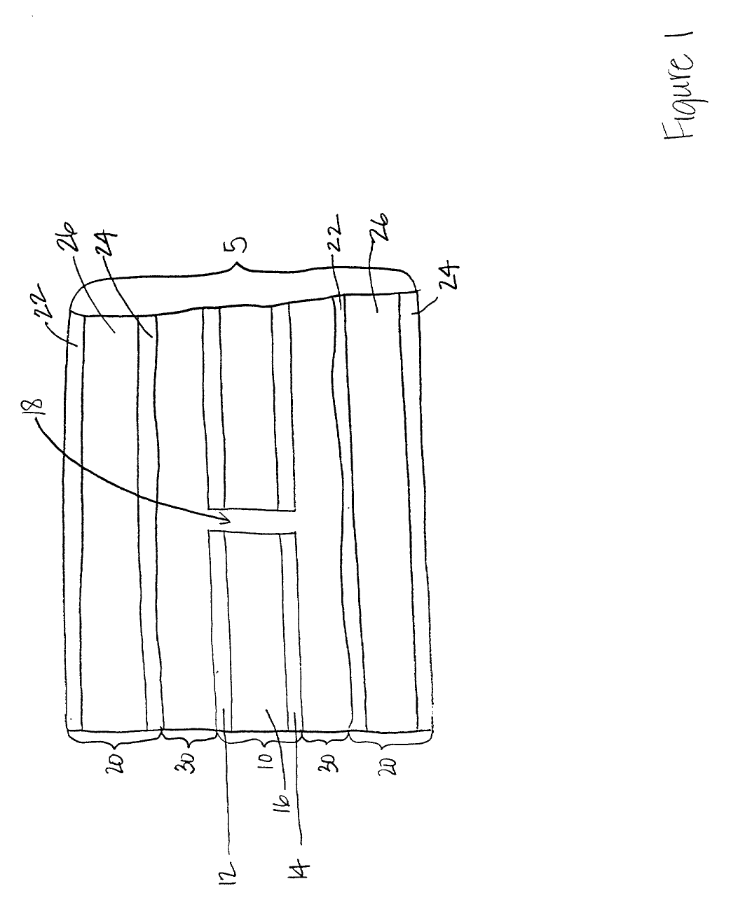

FIG. 1 shows a conventional two-layer sublamination layer 5 that may be used to build up a layered component or circuit board. The sublamination layer 5 comprises three distinct components: a) a signal pair layer 10, b) two reference layers or planes 20, and c) two layers of bond-ply or adhesive 30.

A conventional signal pair layer 10 generally comprises two signal layers 12 and 14 that are separated by a dielectric layer 16. The signal layers 12 and 14 generally are comprised of copper. The signal layers 12 and 14 also have vias 18, or tiny holes, drilled through them and the dielectric material 16 in order to connect layers or to fill with conductive pastes or other materials. The dielectric material 16 functions to control signal integrity and can comprise any suitable dielectric material—whether continuous or porous.

The reference layers 20 in a conventional sublam layer 5 functions to control impedance from the closest signal layer and to provide either ground or power to the board. Each signal layer has a corresponding reference layer. In this example, the reference layers 20 comprise two layers of metal foil 22 and 24 and one layer of dielectric material 26. As with the signal layers 12 and 14, the metal foil layers 22 and 24 generally comprise any conductive metal, such as copper. The dielectric material can comprise any suitable dielectric material—whether continuous or porous.

The layers of bond-ply or adhesive 30 hold together the signal layer pair 10 with the reference layers 20. In general, the bond-ply material 30 can be any suitable tacky or adhesive material, however, in most embodiments, the bond-ply material is just an uncured state of the dielectric materials used in the signal layer pair 10 or the reference planes 20. Once the layers are assembled, the layered structure is cured and the bond-ply becomes another dielectric layer.

Although these conventional sublam layers have been functional, they are considered bulky and thicker than what is desirable for a scaled down component. The conventional sublam layers continue to be produced and used because the materials involved—i.e. preproduced signal pairs and reference planes—are thicker and easier to work with and assemble into boards. Further, quality control of lay-ups or boards comprising conventional sublam materials was difficult because with each layer of additional material came the possibility of defects or errors in the component, along with different thicknesses in several layers that were intended to be the same thickness.

As contemplated herein, sublamination layers or materials have been designed that allow a printed circuit board, in which the sublam layers are incorporated, to fimction with half as many reference planes when using dual strip line technology. Among other benefits, the use of the single reference plane contemplated herein will make it possible to delete one metal layer and two dielectric layers for each signal layer pair used in the lay-up. Also, the production of a thinner circuit board will in turn allow the plated vias to be drilled at a smaller diameter—leading to a smaller pad stack and more area on the circuit board for additional signal lines. The additional signal lines will further allow designers to use devices with higher input/output counts.

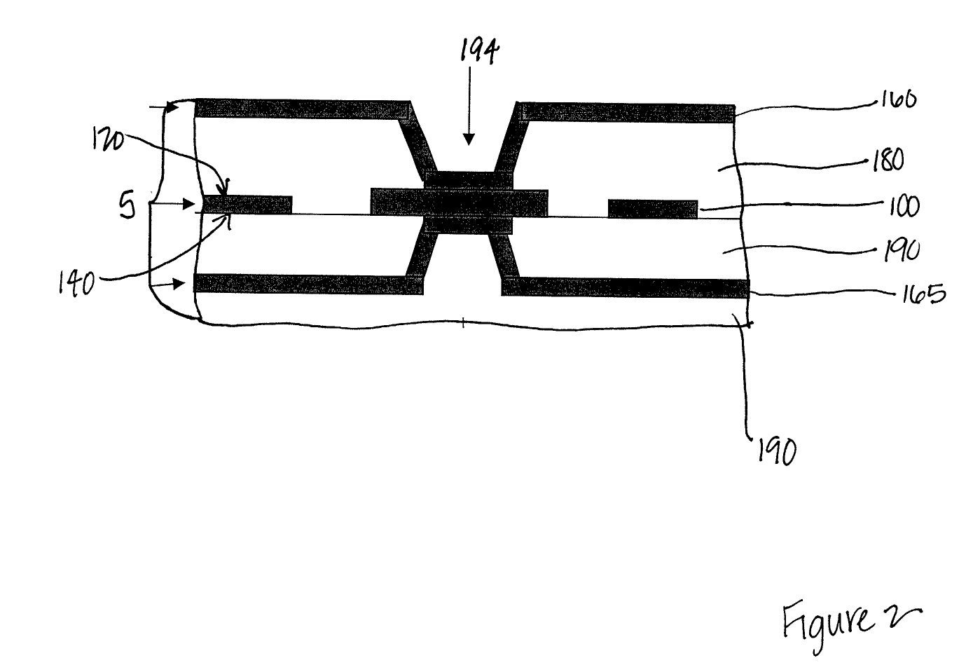

In FIG. 2, a sublamination layer 5 or “sublam” layer 5 contemplated herein comprises a) a single layer etched reference plane 100 having a top surface 120 and a bottom surface 140; b) a first signal layer 160 coupled to the top surface 120 with a core material 180; c) a second signal layer 165 coupled to the bottom surface 140 with a bond-ply material 190; and d) at least one of a blind or a micro via 194.

The single layer, etched reference plane 100 replaces the conventional double-layer reference plane and is contemplated herein to comprise any suitable material that can also function to control impedance in the sublam layer 5 along with a pad that the vias are coupled to. Generally, the reference plane 100 comprises a metal or other conductive material. As used herein, the term “metal” means those elements that are in the d-block and f-block of the Periodic Chart of the Elements, along with those elements that have metal-like properties, such as silicon and germanium. As used herein, the phrase “d-block” means those elements that have electrons filling the 3d, 4d, 5d, and 6d orbitals surrounding the nucleus of the element. As used herein, the phrase “f-block” means those elements that have electrons filling the 4f and 5f orbitals surrounding the nucleus of the element, including the lanthanides and the actinides. Preferred metals include titanium, silicon, cobalt, copper, nickel, zinc, vanadium, aluminum, chromium, platinum, gold, silver, tungsten, molybdenum, cerium, promethium, palladium, rhodium, and thorium. More preferred metals include titanium, silicon, copper, nickel, platinum, gold, silver and tungsten. Most preferred metals include titanium, silicon, and copper. The term “metal” also includes alloys, metal/metal composites, metal ceramic composites, metal polymer composites, as well as other metal composites.

The single-layer, etched reference plane 100 can also be any suitable thickness, depending on the needs of the customer or the component. In a preferred embodiment, the reference plane 100 is not the same thickness as either the first signal layer 160 or the second signal layer 165. In more preferred embodiments, the reference plane 100 is thicker than the first signal layer 160 or the second signal layer 165. For example, in one preferred embodiment, the reference plane 100 is 2.1 millimeters thick, while the first signal layer 160 and second signal layer 165 are 1.5 millimeters thick. In some embodiments, it may also be advantageous for the first signal layer 160 and second signal layer 165 to have different thicknesses from one another.

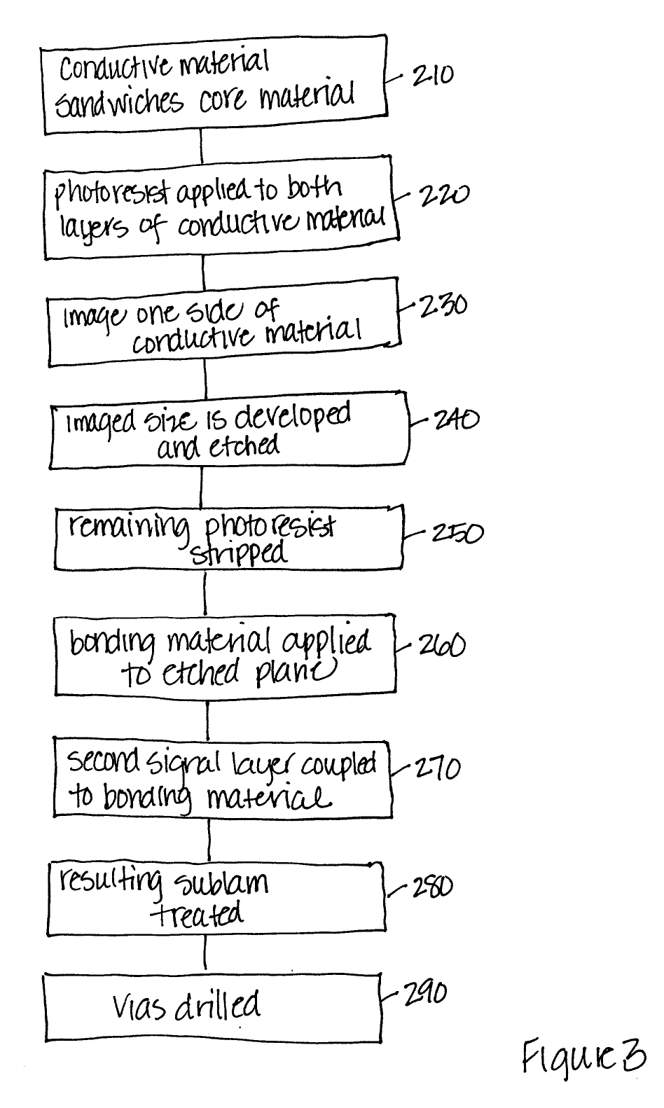

The single-layer reference plane 100 is also etched during introduction into the sublam layer 5. FIG. 3 shows a preferred method 200 of etching the single-layer reference plane 100. A core material 180 is provided that is sandwiched on both sides by a layer of conductive material 210. A photoresist material is applied to both layers of conductive material 220. One side of conductive material is imaged 230. The imaged side of the conductive material is developed and etched 240. The remaining photoresist material is stripped from both sides of the layers of conductive material 250. The etched conductive material is now referred to as the single layer, etched reference plane 100. The non-etched conductive material is now referred to as the first signal layer 160 and is attached to the core material 180, as is the reference plane 100. A layer of bonding material 190 is applied 260 to the etched reference plane 100. A second signal layer 165 is coupled 270 with the bonding material 190. The resulting three-layer sublam layer 5 is treated 280 to cure the bonding material 190. At least one of a blind or micro via 194 is drilled 290 into the sublam layer 5.

The single-layer, etched reference plane 100 has a top surface 120 and a bottom surface 140. A core material or other suitable core-type of material is attached to the top surface 120 and a bonding material 190 is attached to the bottom surface 140 of the reference plane 100. Core material 180 is coupled to the top surface of the reference plane 100 and bonding material 190 is coupled to the bottom surface of the reference plane 100.

Core materials 180 and bonding materials 190 may comprise any suitable adhesive, resin, laminate, bond-ply, polymer, monomer, or pre-preg material. It is contemplated that bonding materials 190 will act as a dielectric material once the sublam layer 5 is cured and core material 180 will act as a dielectric material immediately upon incorporation between the two conductive layers. In preferred embodiments, the core material 180 and the bonding material 190 will comprise the same basic material—with the core material 180 being the “cured” version of the bonding material 190. However, the component, customer or electronic product may require that core material 180 and bonding material 190 comprise different chemical compounds. In contemplated embodiments, the core materials 180 and bonding materials 190 comprise epoxy, cyanate esters, polyimides, TEFLON™ (including ceramic loaded), film based thermoplastics, BT (TRIAZINE/BISMALEMIDE), PPE, glass reinforced compounds, and any combination of the above-mentioned materials. In more preferred embodiments, the core materials 180 and bonding materials 190 comprise one of FR4 epoxy or BT (TRIAZINE/BISMALEMIDE).

Contemplated polymers may also comprise a wide range of functional or structural moieties, including aromatic systems, and halogenated groups. Furthermore, appropriate polymers may have many configurations, including a homopolymer, and a heteropolymer. Moreover, alternative polymers may have various forms, such as linear, branched, super-branched, or three-dimensional. The molecular weight of contemplated polymers spans a wide range, typically between 400 Dalton and 400000 Dalton or more.

As used herein, the term “monomer” refers to any chemical compound that is capable of forming a covalent bond with itself or a chemically different compound in a repetitive manner. The repetitive bond formation between monomers may lead to a linear, branched, super-branched, or three-dimensional product. Furthermore, monomers may themselves comprise repetitive building blocks, and when polymerized the polymers formed from such monomers are then termed “blockpolymers”. Monomers may belong to various chemical classes of molecules including organic, organometallic or inorganic molecules. The molecular weight of monomers may vary greatly between about 40 Dalton and 20000 Dalton. However, especially when monomers comprise repetitive building blocks, monomers may have even higher molecular weights. Monomers may also include additional groups, such as groups used for crosslinking.

As used herein, the term “crosslinking” refers to a process in which at least two molecules, or two portions of a long molecule, are joined together by a chemical interaction. Such interactions may occur in many different ways including formation of a covalent bond, formation of hydrogen bonds, hydrophobic, hydrophilic, ionic or electrostatic interaction. Furthermore, molecular interaction may also be characterized by an at least temporary physical connection between a molecule and itself or between two or more molecules.

The first signal layer 160 and the second signal layer 165 are contemplated to comprise materials similar to those discussed previously as suitable for single-layer, etched reference plane 100, including metals, metal alloys, metal composites, materials for producing optical components, such as wave-guides, and materials and compounds that can conduct electrons or photons. In preferred embodiments, the first signal layer 160 and the second signal layer 165 comprise copper. In other preferred embodiments the first signal layer 160 and the second signal layer 165 are the same material. However, it is contemplated that the signal layers may comprise different materials, if the needs of the customer, the component or the product require or demand that the two signal layers comprise different materials.

Once the single-layer, etched reference plane 100 and first signal layer 160 is combined with the core materials 180 and the bonding materials 190 and then further combined with the second signal layer 165, the three-layered stack is cured at conditions prescribed by the type or types of core materials 180 and bonding materials 190 that have been used in the stack. For example, FR4 may require a completely different temperature and pressure curing cycle than a cyanate ester bond-ply.

Before the cured sublam layer 5 is incorporated into a layered component, at least one blind via or micro via 194 is drilled into the sublam layer 5. Blind or micro vias are tiny holes that are drilled directly through one signal layers and either the core or bonding material to the reference plane 100. The via is then covered with another material, thus making it a “blind” via 194. These blind and micro vias 194 can be drilled either with conventional drilling tools, chemicals or with lasers. Vias 194 are important for the layered components because they are used to interconnect layers, store other conductive materials and provide a foundation for other components in the component.

Although several different materials and preferred combinations have been previously described for the components of the sublamination layers 5, it should be realized that the composition of the sublam layer 5 is directly dependent on the needs of the customer, the component or the product. In order for the vendor of the sublam layer 5 to gauge the needs of the customer, the component and/or the product, the vendor must have a method of receiving as much information from the customer as possible.

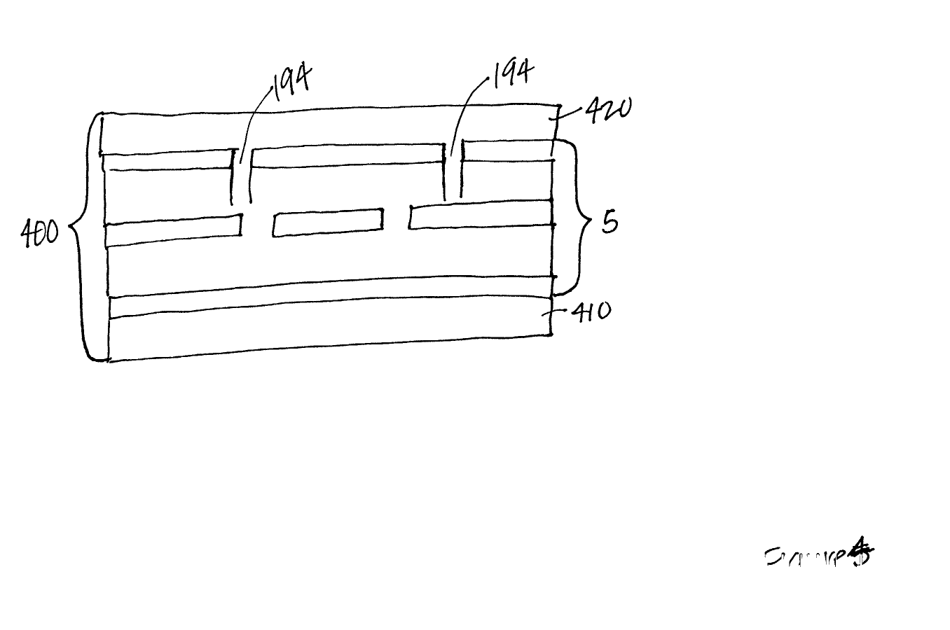

In FIG. 4, an electronic component 400 can be produced comprising the sublamination material 5 contemplated herein. The electronic component 400 comprises a) a substrate layer 410; b) a sublamination layer or sublamination material 5; and c) at least one additional layer 420. The electronic component 400 contemplated herein should have fewer layers than electronic components comprising conventional sublamination layers or materials.

Substrates and substrate layers 410, used herein interchangeably, contemplated herein may comprise any desirable substantially solid material. Particularly desirable substrate layers 410 would comprise films, glass, ceramic, plastic, metal or coated metal, or composite material. In preferred embodiments, the substrate 410 comprises a silicon or germanium arsenide die or wafer surface, a packaging surface such as found in a copper, silver, nickel or gold plated leadframe, a copper surface such as found in a circuit board or package interconnect trace, a via-wall or stiffener interface (“copper” includes considerations of bare copper and it's oxides), a polymer-based packaging or board interface such as found in a polyimide-based flex package, lead or other metal alloy solder ball surface, glass and polymers such as polyimides, BT (TRIAZINE/BISMALEMIDE), and FR4. In more preferred embodiments, the substrate 410 comprises a material common in the packaging and circuit board industries such as silicon, copper, glass, and another polymer.

Substrate layers 410 contemplated herein may also comprise at least two layers of materials. One layer of material comprising the substrate layer 410 may include the substrate materials previously described. Other layers of material comprising the substrate layer 410 may include layers of polymers, monomers, organic compounds, inorganic compounds, organometallic compounds, continuous layers and nanoporous layers.

The substrate layer 410 may also comprise a plurality of voids if it is desirable for the material to be nanoporous instead of continuous. Voids are typically spherical, but may alternatively or additionally have any suitable shape, including tubular, lamellar, discoidal, or other shapes. It is also contemplated that voids may have any appropriate diameter. It is further contemplated that at least some of the voids may connect with adjacent voids to create a structure with a significant amount of connected or “open” porosity. The voids preferably have a mean diameter of less than 1 micrometer, and more preferably have a mean diameter of less than 100 nanometers, and still more preferably have a mean diameter of less than 10 nanometers. It is further contemplated that the voids may be uniformly or randomly dispersed within the substrate layer. In a preferred embodiment, the voids are uniformly dispersed within the substrate layer 410.

Thus, it is contemplated that the substrate layer 410 may comprise a single layer of conventional substrate material. It is alternatively contemplated that the substrate layer 410 may comprise several layers, along with the conventional substrate material, that function to build up part of electronic component 400.

Suitable materials that can be used in additional substrate layers 410 comprise any material with properties appropriate for a printed circuit board or other electronic component, including pure metals, alloys, metal/metal composites, metal ceramic composites, metal polymer composites, cladding material, laminates, conductive polymers and monomers, as well as other metal composites.

A layer of laminating material or cladding material can be coupled to the substrate layer 410 or the sublamination layer 5 depending on the specifications required by the component. Laminates are generally considered fiber-reinforced resin dielectric materials. Cladding materials are a subset of laminates that are produced when metals and other materials, such as copper, are incorporated into the laminates. (Harper, Charles A., Electronic Packaging and Interconnection Handbook, Second Edition, McGraw-Hill (New York), 1997.)

Additional layers of material 420 may be coupled to the sublamination layer 5 in order to continue building a layered component or printed circuit board 400. It is contemplated that the additional layers 420 will comprise materials similar to those already described herein, including metals, metal alloys, composite materials, polymers, monomers, organic compounds, inorganic compounds, organometallic compounds, resins, adhesives and optical wave-guide materials.

### EXAMPLES

Manufacture Copper Reference Plane

Use copper weight required by customer for current carrying capacity requirement. Test vehicles have been run using 1½-oz (1.8 mil) copper. However, depending on application either lighter or heavier copper weights can be substituted.

Clean and etch the core material. Apply the photoresist to both sides of the copper-core material-copper material. Image one side of the photoresist. Develop and etch the imaged side of the photoresist. Strip the remaining photoresist from both sides. This leaves a core with an etched plane pattern on one side and solid copper on the other side that may have registration targets etched into it. Inspect and oxide treat the core.

Preparation of Sublamination Material or Layers

Laminate the second copper signal layer to the reference plane by using bond-ply materials or other adhesives. The lamination cycle will vary depending of the type dielectric that is chosen. (See Table 1 below)

TABLE 1
Dielectric bond ply materials to be used but limited to in the
three layer micro via layer

| | | | | lamination | lamination |
|---|---|---|---|---|---|
| Tg | material | material | lamination | temperature | pressure |
| Celsius | type | base | dwell | Celsius | (PSI) |
| 140 | FR4 epoxy | glass reinforced | 45 minutes | 177 | 250 |
| | | | | degrees | |
| 170 | FR4 epoxy | glass reinforced | 80 minutes | 182 | 250 |
| | | | | degrees | |
| 170 | FR4 epoxy | resin coated foil* | 80 minutes | 182 | 250 |
| | | | | degrees | |
| 180 | BT | glass reinforced | 80 minutes | 191 | 350 |
| | (TRIAZINE/ | | | degrees | |
| | BISMALEMIDE) | | | | |
| 190 | Asahi | PPO | 80 minutes | 182 | 350 |
| 190 | Cyanate | glass reinforced | 80 minutes | 191 | 350 |
| | ester | | | degrees | |
| 190 | Cyanate | Teflon | 80 minutes | 191 | 350 |
| | ester | (Speedboard) | | degrees | |
| 260 | polyimide | glass reinforced | 120 | 218 | 350 |
| | | | minutes | degrees | |
| 297** | LCP | Film | 30 minutes | 273 | 500 |
| | | | | degrees | |

*stackup would include dielectric and copper as one
**Melt temp.

Remove excess flash from lamination resin flow. Register tooling holes to layer 2 images for drilling by laser exposing fiducials. Drill via holes either by conventional drill bit method or by laser method. All holes must fall within etched clearances in reference plane. Hole prep in the permanganate. Electroless copper plate the panel. Coat panel with photoimagible resist. Expose using pattern plate image polarity on layer 1 and layer 3. Develop away-unwanted photo resist. Copper pattern plate the panel. Tin pattern plate the panel. Strip the photo resist. Alkaline etch features to required sizes. Strip tin from copper features. Automatic optical inspect signal layers. Include “three layer micro vias” in with rest of layers to be laminated into final board.

Thus, specific embodiments and applications of electronic components comprising sublamination materials have been disclosed. It should be apparent, however, to those skilled in the art that many more modifications besides those already described are possible without departing from the inventive concepts herein. The inventive subject matter, therefore, is not to be restricted except in the spirit of the appended claims. Moreover, in interpreting both the specification and the claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

What is claimed is:

1. A sublamination material, comprising:
a single layer reference plane having a top surface and a bottom surface;
a first signal layer coupled to the top surface with a core material;
a second signal layer coupled to the bottom surface with a bond-ply material; and
at least one of a blind via or a micro via.

2. The sublamination material of claim 1, wherein the reference plane comprises a conductive material.

3. The sublamination material of claim 2, wherein the conductive material is copper.

4. The sublamination material of claim 1, wherein the first signal layer comprises the same material as the second signal layer.

5. The sublamination material of claim 1, wherein the first signal layer is copper.

6. The sublamination material of claim 1, wherein the bond-ply material comprises the same material as the core material.

7. The sublamination material of claim 1, wherein the core material is a dielectric material.

8. The sublamination material of claim 7, wherein the dielectric material is FR4.

9. The sublamination material of claim 1, wherein the second signal layer comprises copper.

10. The sublamination material of claim 1, wherein the bond-ply material is a dielectric material.

11. The sublamination material of claim 10, wherein the dielectric material is BT.

12. The sublamination material of claim 1, wherein the blind via is formed by using a laser or a conventional drill.

13. A method of producing a sublamination material, comprising:
providing a core material, wherein the core material is sandwiched on both sides by a layer of conductive material;
applying a photoresist to the layers of conductive material;
imaging one layer of the conductive material to produce an imaged layer of conductive material;
developing and etching the imaged layer of the conductive material to produce an etched layer of conductive material;
stripping the photoresist from both layers of conductive material;
applying a bonding material to the etched layer of conductive material;
coupling a second metal layer to the bonding material to form a layered stack;
curing the layered stack; and
drilling at least one blind via or micro via into the sublamination material.

14. The method of claim 13, wherein the layer of conductive material is copper.

15. The method of claim 13, wherein the bonding material is FR4.

16. A method for producing an electronic component, comprising:
providing a substrate;
coupling at least one sublamination material to the substrate; and
coupling at least one additional layer to the sublamination material.

17. The method of claim 16, wherein the substrate is a silicon wafer.

18. The method of claim 16, wherein the sublamination material is the sublamination material of claim 1.

19. The method of claim 16, wherein the additional layer is a laminate.

20. The method of claim 16, wherein the electronic component comprises a printed circuit board.
